(19) United States
(12) Patent Application Publication
(10) Pub. No.: US 2024/0006420 A1
(43) Pub. Date: Jan. 4, 2024

(54) SUBSTRATE PACKAGE AND DISPLAY DEVICE INCLUDING THE SAME

(71) Applicant: STEMCO CO., LTD., Cheongju-si (KR)

(72) Inventor: Jin Han LEE, Cheongju-si (KR)

(73) Assignee: STEMCO CO., LTD., Cheongju-si (KR)

(21) Appl. No.: 18/468,553

(22) Filed: Sep. 15, 2023

Related U.S. Application Data
(63) Continuation of application No. PCT/KR2022/004183, filed on Mar. 25, 2022.

(30) Foreign Application Priority Data
Mar. 26, 2021 (KR) 10-2021-0039255

(51) Int. Cl. H01L 27/12; H01L 25/065

(52) U.S. Cl. CPC H01L 27/124; H01L 25/0655

(57) ABSTRACT

A substrate package in which chip-on-films (COFs) are attached to both surfaces of a display panel and a display device including the substrate package are provided. The display device includes: a display panel displaying data on a screen; and a plurality of first packages and a plurality of second packages where chips for driving the display panel are installed, the first packages and the second packages being attached to an end portion of the display panel, wherein the first packages and the second packages are attached through different surfaces of the display panel.

### CROSS-REFERENCE TO RELATED APPLICATIONS

This application is a Continuation of International Application No. PCT/KR2022/004183 filed Mar. 25, 2022, which claims benefit of priority to Korean Patent Application No. 10-2021-0039255 filed Mar. 26, 2021, the entire contents of which are incorporated herein by reference.

### TECHNICAL FIELD

The present disclosure relates to a substrate package and a display device including the same, and more particularly, to a substrate package applicable to a flat panel display device and a display device including the substrate package.

### BACKGROUND ART

Display devices, which are media that convey visual information, visually present data in the form of characters or geometric figures on their screen.

Recently, flat panel display (FPD) devices have gained prominence. Depending on their types, FPD devices may be categorized as liquid crystal displays (LCDs), plasma display panels (PDPs), electro luminescent displays (ELDs), organic light-emitting diode (OLED) displays, or micro-LED displays.

To achieve resolution in display devices, n chip-on-films (COFs) may be attached to the end of a display panel (where n is a natural number of 1 or greater). In this case, the n COFs may be attached in a row along the end of the display panel, maintaining a consistent spacing to prevent operational defects.

Recent demands for display devices include lightweight design, compact size, high resolution, and advanced functionality. To meet these demands, it is inevitable to increase the number of COFs attached to a display panel. However, this may lead to a considerable reduction in the spacing between the COFs.

### DISCLOSURE

### Technical Problems

To address the aforementioned problems, exemplary embodiments of the present disclosure provide a substrate package in which chip-on-films (COFs) are attached on both surfaces of a panel and a display device including the substrate package.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

### Technical Solutions

According to an aspect of the present disclosure, a display device includes: a display panel displaying data on a screen; and a plurality of first packages and a plurality of second packages where chips for driving the display panel are installed, the first packages and the second packages being attached to an end portion of the display panel, wherein the first packages and the second packages are attached through different surfaces of the display panel.

The first packages and the second packages may be staggered with each other.

The first packages and the second packages may be arranged in parallel to each other along a length direction of the display panel.

The first packages and the second packages may at least partially overlap with each other.

The first packages and the second packages may be chip-on-films (COFs).

The first packages and the second packages may be arranged such that their surfaces where the chips are installed are oriented in the same direction.

The first packages and the second packages may be arranged such that their surfaces where the chips are installed are oriented in opposite directions.

Among the first packages, two different first packages may be attached at a distance from each other.

The distance between the two different first packages may vary depending on a type of the display panel.

The distance between the two different first packages may vary depending on a length and channel quantity of the first packages, resolution, subpixel quantity, and a length of one side of the display panel.

The first packages and the second packages may be bent over toward one surface or the other surface of the display panel after attached to the display panel.

According to an aspect of the present disclosure, a substrate package attached to an end portion of a display panel, which displays data on a screen, includes: a plurality of first packages and a plurality of second packages where chips for driving the display panel are installed, the first packages and the second packages being attached to an end portion of the display panel, wherein the first packages and the second packages are attached through different surfaces of the display panel.

It should be noted that the effects of the present disclosure are not limited to those described above, and other effects of the present disclosure will be apparent from the following description.

### Advantageous Effects

According to the present disclosure, the following effects can be achieved.

First, by attaching chip-on-films (COFs) to both surfaces of a display panel, the number of COFs can be increased while uniformly maintaining the distance between the COFs.

Second, a high-resolution display can be realized by increasing the number of COFs.

### BRIEF DESCRIPTION OF DRAWINGS

FIG. 1 is a schematic front view illustrating the internal configuration of a display device according to a first embodiment of the present invention;

FIG. 2 is a schematic bottom view illustrating the internal configuration of the display device according to the first embodiment of the present invention;

FIG. 3 is a schematic front view illustrating the internal configuration of a display device according to a second embodiment of the present invention;

FIG. 4 is a schematic bottom view illustrating the internal configuration of the display device according to the second embodiment of the present invention;

FIG. 5 is a schematic bottom view illustrating the internal configuration of a display device according to a third embodiment of the present invention;

FIG. 6 is a schematic bottom view illustrating the internal configuration of a display device according to a fourth embodiment of the present invention;

FIG. 7 presents a first exemplary table showing first package distances and second package distances for display devices according to various embodiments of the present invention;

FIG. 8 presents a second exemplary table showing the first package distances and the second package distances for display devices according to various embodiments of the present invention; and

FIG. 9 presents a third exemplary table showing the first package distances and the second package distances for display devices according to various embodiments of the present invention.

### BEST MODES FOR CARRYING OUT THE INVENTION

Preferred embodiments of the present invention will hereinafter be described with reference to the accompanying drawings. The advantages and features of the present invention, as well as the methods for achieving them, will become clear by referring to the detailed embodiments provided with the attached drawings. However, it should be noted that the present invention is not limited to the disclosed embodiments but can be implemented in various different forms. The disclosed embodiments are provided to fully disclose the invention to those skilled in the art and to inform them of the scope of the invention in the technical field to which the invention pertains. The entire specification uses the same reference numerals to denote identical components.

When referring to a component or a layer as being “on” or “above” another component or layer, it includes cases where there is another layer or a different component in between. On the other hand, when a component is referred to as “directly on” or “right on top,” it indicates that there is no other layer or component in between.

Spatially relative terms such as “below,” “beneath,” “lower,” “above,” “upper,” etc., are used to facilitate the description of relationships between one component or element and another component or element, as depicted in the drawings. These spatially relative terms should be understood to include the directions in the drawings and may include different orientations of the components during operation or use. For example, when a component shown in the drawings is flipped, a component described as “below” or “beneath” another component can be placed “above” the other component. Therefore, the term “below,” as an illustrative example, can encompass both directions of below and above. Components can also be oriented in different directions, and thus, spatially relative terms can be interpreted based on the orientations.

While terms such as “first,” “second,” and the like are used to describe various components, elements, and/or sections, it should be understood that these components, elements, and/or sections are not limited by these terms. These terms are merely used to distinguish one component, element, or section from another. Therefore, the “first” component, “first” element, or “first” section mentioned below may also refer to the “second” component, “second” element, or “second” section within the technical scope of the present invention.

The terms used in this specification are intended to describe exemplary embodiments and are not intended to limit the invention. In this specification, the singular form includes the plural form unless specifically mentioned otherwise. The terms “comprises” and/or “comprising” used in the specification do not exclude the presence or addition of one or more other components, steps, operations, and/or elements as described.

Unless otherwise defined, all terms used in this specification (including technical and scientific terms) are intended to have the meaning commonly understood by those skilled in the art to which the present invention belongs. Additionally, terms that are generally defined in dictionaries are not to be interpreted overly or excessively unless explicitly defined otherwise.

Embodiments of the present invention will hereinafter be described in detail with reference to the accompanying drawings. When describing the embodiments with reference to the accompanying drawings, components that are the same or corresponding, regardless of drawing symbols, will be assigned the same reference numbers, and redundant descriptions for them will be omitted.

The present invention relates to a substrate package in which chip-on-films (COFs) are attached on both surfaces of a panel and a display device including the substrate package. The present invention will hereinafter be described with reference to the accompanying drawings.

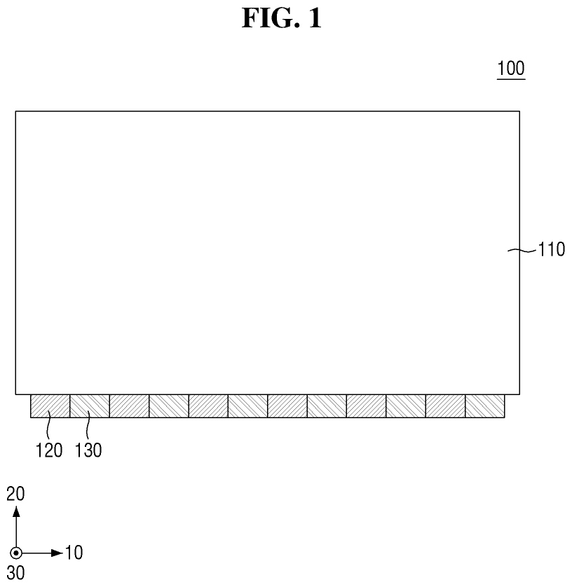

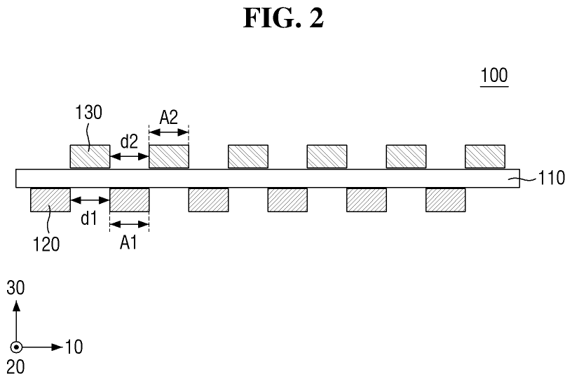

FIG. 1 is a schematic front view illustrating the internal configuration of a display device according to a first embodiment of the present invention, and FIG. 2 is a schematic bottom view illustrating the internal configuration of the display device according to the first embodiment of the present invention.

Referring to FIGS. 1 and 2, a display device 100 may be configured to include a display panel 110, first packages 120, and second packages 130.

The display panel 110 displays data such as text and an image on a screen. The display panel 110 may be disposed at the front of the display device 100.

The display panel 110 may be fabricated as a flexible panel and may be disposed on the front surface, both side surfaces, and back surface of the display device 100. Additionally, multiple display panels 110 may be provided within the display device 100 and may be positioned on one or more surfaces of the display device 100.

The first packages 120 and the second packages 130 may accommodate therein semiconductor chips for driving the display panel 110. The first packages 120 and the second packages 130 are collectively defined as a substrate package.

The first packages 120 and the second packages 130 may be attached to one end of the display panel 110. For example, the first packages 120 and the second packages 130 may be attached to a lower end portion of the display panel 110.

However, the present embodiment is not limited to this. The first packages 120 and the second packages 130 may be attached to multiple end portions of the display panel 110. The first packages 120 and the second packages 130 may be attached to, for example, one side portion and the lower end portion of the display panel 110.

The first packages 120 and the second packages 130 may be attached to the same multiple end portions of the display panel 110, but the present disclosure is not limited thereto. Alternatively, the first packages 120 and the second packages 130 may be attached to different end portions of the display panel 110 from each other. For example, the first packages 120 may be attached to the lower end portion of the display panel 110, and the second packages 130 may be attached to one side portion of the display panel 110.

The first packages 120 and the second packages 130 may be implemented as COFs with integrated circuits (ICs) mounted thereon. The first packages 120 and the second packages 130 may be, for example, COFs with ICs for sources mounted thereon or COFs with ICs for gates mounted thereon.

Meanwhile, in the present embodiment, each of the first packages 120 may be a COF with one of an IC for a source and an IC for a gate mounted thereon, and each of the second package 130 may be a COF with the other IC mounted thereon.

The first packages 120 and the second packages 130 will hereinafter be described as being attached to the same end portion of the display panel 110, for example, the lower end portion of the display panel 110. The same method may also be applied when multiple first packages 120 and multiple second packages are provided and are attached to different end portions of the display panel 110 from each other.

The first packages 120 may be attached to one surface edge of the display panel 110. For example, the first packages 120 may be attached to a front surface edge of the display panel 110. In this example, the first packages 120 may be implemented as surface-attachment COFs.

On the other hand, the second packages 130 may be attached to the opposite surface edge of the display panel 110. For example, the second packages 130 may be attached to a back surface edge of the display panel 110. In this example, the second package 130 may be implemented as back-attachment COFs.

When the first packages 120 and the second packages 130 are attached to both surface edges of the display panel 110, the first packages 120 and the second packages 130 may be arranged in parallel to each other along the length direction of the display panel 110 (or a first direction 10). For example, the first packages 120 and the second packages 130 may be arranged in a zigzag pattern along the length direction of the display panel 110 (or the first direction 10).

To achieve a resolution of αK in the display panel 110, n COFs (where n is a natural number of 1 or greater) may be attached to the surface of the display panel 110. In this case, every two adjacent COFs may be spaced apart by a distance χ.

However, when the resolution of the display panel 110 is raised to 2αK, the required number of COFs also doubles, and as a result, the distance between every two adjacent COFs is reduced to χ/2.

In the present embodiment, 2n COFs (i.e., the first packages 120 and the second packages 130), which are needed for implementing the resolution of 2αK, are divided into two sets of n COFs and may be respectively attached to the front and back surfaces of the display panel 110.

Consequently, the surface-attachment COFs (i.e., the first packages 120) and the back-attachment COFs (i.e., the second packages 130) may be arranged in a zigzag pattern when observed from the normal direction of the display panel 110. Therefore, a package structure capable of achieving the resolution of 2αK while uniformly maintaining the distance between every two adjacent COFs at the same level (i.e., χ) as before can be provided.

Meanwhile, in a case where a panel circuit for implementing a screen is formed on one surface of the display panel 110 (e.g., the surface where the second packages 130 are attached), vias may be formed on the display panel 110 to extend the panel circuit to the opposite surface of the display panel 110 and connect the panel circuit to the first packages 120.

If the first packages 120 and the second packages 130 are arranged in a zigzag pattern along the length direction of the display panel 110 (or the first direction 10), wiring issues between COFs can be addressed. However, the present embodiment is not limited to this. The first packages 120 and the second packages 130 may also be positioned at corresponding locations on the front and back surfaces, respectively, of the display panel 110.

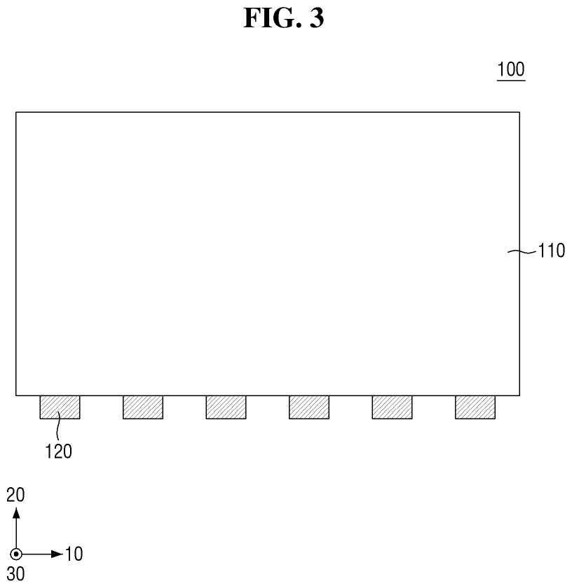

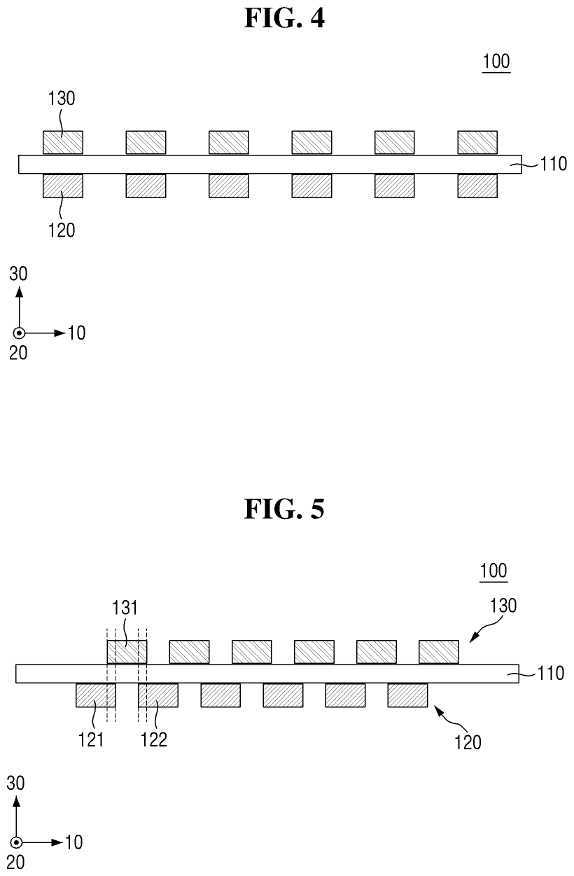

For example, as illustrated in FIGS. 3 and 4, the first packages 120 and the second packages 130 may be disposed at the front and rear, respectively, of the display panel 110. FIG. 3 is a schematic front view illustrating the internal configuration of a display device according to a second embodiment of the present invention, and FIG. 4 is a schematic bottom view illustrating the internal configuration of the display device according to the second embodiment of the present invention.

The following description continues referring back to FIG. 1.

When the first packages 120 and the second packages 130 are arranged in a zigzag pattern along the length direction of the display panel 110 (or the first direction 10) with two different first packages 120 positioned on either side of each second package 130, one end of the corresponding second package 130 may be positioned on the same line as the end of one of the two different first packages 120, and the other end of the corresponding second package 130 may be positioned on the same line as the end of the other first package 120.

However, the present embodiment is not limited to this. As illustrated in FIG. 5, in a case where two different first packages 120, i.e., first packages 121 and 122, are arranged on either side of a second package 131, one end of the second package 131 may partially overlap with the end of one of the two first packages 120, i.e., the end of the first package 121, and the other end of the second package 131 may partially overlap with the end of the other first package 120, i.e., the end of the first package 122.

Here, both ends of the second package 131 may partially overlap with the ends of the first packages 121 and 122, but the second package 131 may partially overlap with the end of only one of the two different first packages 121 and 122. FIG. 5 is a schematic bottom view illustrating the internal configuration of a display device according to a third embodiment of the present invention.

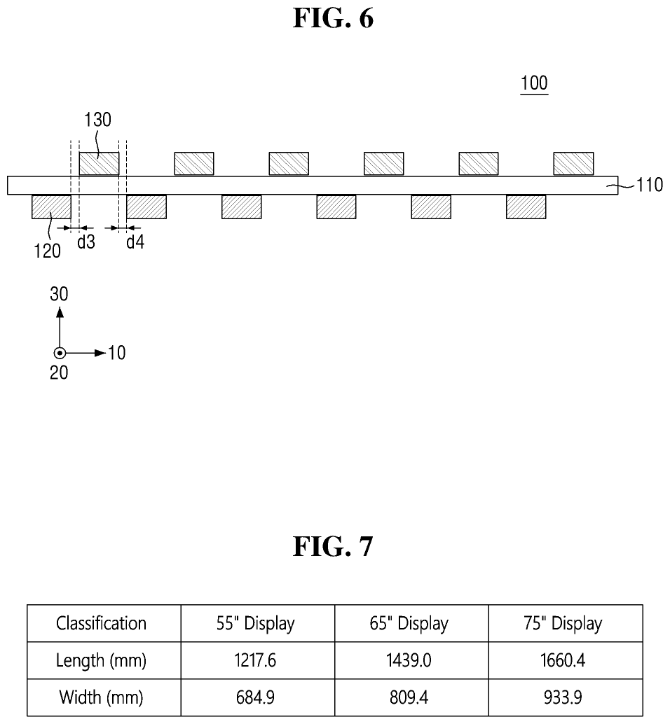

Meanwhile, as illustrated in FIG. 6, in a case where two different first packages 120, i.e., the first packages 121 and 122, are disposed on either side of the second package 131, one end of the second package 131 may be a predetermined distance d3 apart from the end of one of the two different packages 120, i.e., the end of the first package 121, and similarly, the other end of the second package 131 may be a predetermined distance d4 apart from the end of the other first package 120, i.e., the end of the first package 122.

The distance d3 between the ends of the second package 131 and the first package 121 may be the same as the distance d4 between the ends of the second package 131 and the first package 122 (i.e., d3=d4), but alternatively, the distance d3 between the ends of the second package 131 and the first package 121 may differ from the distance d4 between the ends of the second package 131 and the first package 122 (i.e., d3≈d4).

Meanwhile, only one of the ends of the second package 131 may be a predetermined distance apart from the end of the corresponding first package 120, and the other end of the second package 131 may be positioned on the same line as, or partially overlap with, the end of the corresponding first package 120. FIG. 6 is a schematic bottom view illustrating the internal configuration of a display device according to a fourth embodiment of the present invention.

Meanwhile, in the present embodiment, the first packages 120 and the second packages 130 may be bent over toward one surface or the opposite surface of the display panel 110 after attached to the display panel 110.

Meanwhile, when the first packages 120 and the second packages 130 are arranged in parallel to each other along the length direction of the display panel 110 (or the first direction 10), the first packages 120 and the second packages 130 may have the same height or different heights (i.e., in the second direction 20).

The distance between COFs that varies depending on the type of display device will hereinafter be described. Here, the distance between COFs may be applicable to a distance d1 between the first packages 120, which are attached to the end of the front surface of the display panel 110, and also applicable to a distance d2 between the second packages 130, which are attached to the end of the back surface of the display panel 110.

The number of COFs for each given display resolution may be calculated by Equation 1:

Y=X*m/N Equation 1:

Referring to Equation (1), Y denotes the number of COFs, X denotes resolution, m denotes the number of subpixels, m is 3 (R, G, and B), and N denotes the number of patterns (or channels) of a COF with one chip mounted thereon (i.e., a 1-chip mounted COF).

The length that can be allocated when uniformly mounting the number of COFs, calculated in Equation 1, onto a display device can be determined by Equation 2:

w=W/Y Equation 2:

Referring to Equation 2, w denotes the width length where one COF can be placed, W denotes the length of one side of a display device where COFs can be mounted, and Y, which is the value calculated by Equation 1, denotes the number of COFs.

The distance between adjacent COFs that is based on the width length calculated by Equation 2 may be calculated by Equation 3:

S=w−L Equation 3:

Referring to Equation 3, S denotes the distance between COFs. In the present embodiment, the distance S may correspond to the distance d1 between the first packages 120 may also correspond to the distance d2 between the second packages 130. Additionally, w denotes the width length where one COF can be placed, and L denotes the width length (A1 or A2) of COF products. The width length (A1 or A2) of COF products may vary depending on the number of chips being mounted.

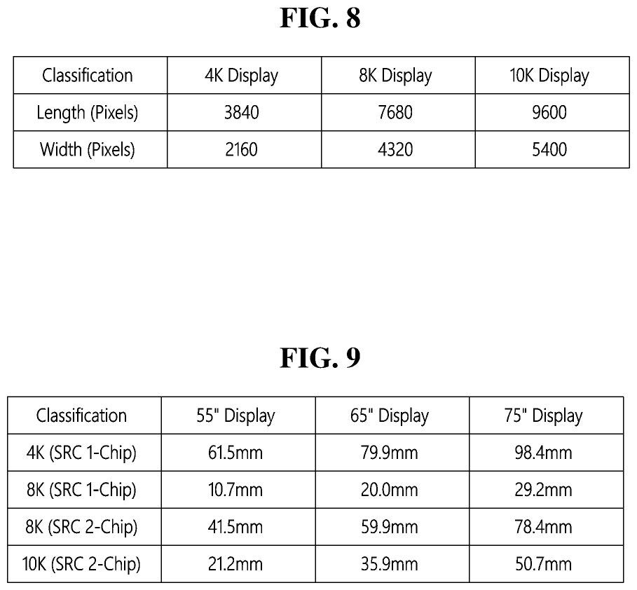

FIGS. 7 through 9 present exemplary tables for explaining COF distances for different display types. The dimensions of a TV display size (or screen size) may be exemplified as shown in FIG. 7, and the resolution of the TV display may be exemplified as shown in FIG. 8. The distance between COFs may be calculated according to Equations 1 through 3 when mounting COFs only on one surface of the display, and the results of the calculation are as shown in FIG. 9.

Referring to FIG. 9, for an 8K(SRC 1-chip) 55″ display, the distance between COFs is 10.7 mm, which is very narrow. However, according to the present invention, by placing COFs (i.e., the first packages 120 and the second packages 130) on both surfaces of the display, the effect of doubling the distance between COFs to 21.4 mm can be achieved.

Also, for an 8K(SRC 1-chip) 43″ display and a 10K(SRC 1-chip) 43″ display, the distance between COFs can be calculated according to Equations 1 through 3, as follows:

(1) 8K & 43″ display (SRC 1-chip)

24=7680*3/960 Equation 1:

39.7=952/24 Equation 2:

−0.3=39.7−40 Equation 3:

(2) 10K & 43″ display (SRC 1-chip)

30=9600*3/960 Equation 1:

31.7=952/30 Equation 2:

−8.3=31.7−40 Equation 3:

In the above cases, the distances between COFs are −0.3 mm and −8.3 mm, respectively, which mean there are overlaps between COFs so that all COFs cannot be placed on one surface of each display. However, according to the present invention, as COFs (i.e., the first packages 120 and the second packages 130) are disposed on both surfaces of each display, the issue of overlapping COFs of FIG. 5 can be resolved.

Meanwhile, it should be noted that the numerical values provided by the aforementioned equations are merely illustrative and may change depending on the type of displays or COFs or the chip design.

Embodiments of the present disclosure have been described above with reference to the accompanying drawings, but the present disclosure is not limited thereto and may be implemented in various different forms. It will be understood that the present disclosure can be implemented in other specific forms without changing the technical spirit or gist of the present disclosure. Therefore, it should be understood that the embodiments set forth herein are illustrative in all respects and not limiting.

### INDUSTRIAL APPLICABILITY

The present invention can be applied to a display device such as a liquid crystal display (LCD) or an organic light-emitting diode (OLED) display.

What is claimed is:

1. A display device comprising:
a display panel displaying data on a screen; and
a plurality of first packages and a plurality of second packages where chips for driving the display panel are installed, the first packages and the second packages being attached to an end portion of the display panel,
wherein the first packages and the second packages are attached through different surfaces of the display panel.

2. The display device of claim 1, wherein the first packages and the second packages are staggered with each other.

3. The display device of claim 1, wherein the first packages and the second packages are arranged in parallel to each other along a length direction of the display panel.

4. The display device of claim 1, wherein the first packages and the second packages at least partially overlap with each other.

5. The display device of claim 1, wherein the first packages and the second packages are chip-on-films (COFs).

6. The display device of claim 1, wherein the first packages and the second packages are arranged such that their surfaces where the chips are installed are oriented in the same direction.

7. The display device of claim 1, wherein the first packages and the second packages are arranged such that their surfaces where the chips are installed are oriented in opposite directions.

8. The display device of claim 1, wherein among the first packages, two different first packages are attached at a distance from each other.

9. The display device of claim 8, wherein the distance between the two different first packages varies depending on a type of the display panel.

10. The display device of claim 8, wherein the distance between the two different first packages varies depending on a length and channel quantity of the first packages, resolution, subpixel quantity, and a length of one side of the display panel.

11. The display device of claim 1, wherein the first packages and the second packages are bent over toward one surface or the other surface of the display panel after attached to the display panel.

12. A substrate package attached to an end portion of a display panel, which displays data on a screen, comprising:
a plurality of first packages and a plurality of second packages where chips for driving the display panel are installed, the first packages and the second packages being attached to an end portion of the display panel,
wherein the first packages and the second packages are attached through different surfaces of the display panel.
